(19) United States
(12) Patent Application Publication
(10) Pub. No.: US 2004/0117704 A1
(43) Pub. Date: Jun. 17, 2004

(54) Semiconductor integrated circuit device with test circuit

(75) Inventor: Hideshi Maeno, Tokyo (JP)

Correspondence Address: BURNS, DOANE, SWECKER & MATHIS, L.L.P., P.O. Box 1404, Alexandria, VA, 22313-1404, US

(73) Assignee: RENESAS TECHNOLOGY CORPORATION

(21) Appl. No.: 10/611,172

(22) Filed: Jul. 2, 2003

(30) Foreign Application Priority Data
Dec. 16, 2002 (JP) 2002-364099

(51) Int. Cl. G01R 31/3177

(52) U.S. Cl. 714/726

(57) ABSTRACT

A semiconductor integrated circuit device has a scan path including parallel paths between a first logic section and a functional block, and a serial shift path for serially transferring data from a scan-in terminal to scan-out terminal. The scan path includes first selectors, flip-flops connected to the outputs of the first selectors, and second selectors interposed into the serial shift path, for connecting one of a set of outputs of the functional block and a set of outputs of the serial shift path to the inputs of a second logic section. The test data from the scan-in terminal is shifted into the functional block via the second and first selectors, and test result data the functional block produces are output from the scan-out terminal after switching the second selectors. It can test the functional block in isolation without increasing the scale of the test circuit.

### BACKGROUND OF THE INVENTION

1. Field of the Invention

The present invention relates to a semiconductor integrated circuit device including a functional block such as a RAM (Random Access Memory), a logic section connected to the functional block, and a test circuit for testing them.

2. Description of Related Art

FIG. 12 is a circuit diagram showing a configuration of a conventional semiconductor integrated circuit device including a scan test function disclosed in a Relevant Reference 1. As shown in FIG. 12, the semiconductor integrated circuit device includes selectors 10, 11 and 12 controlled by a shift mode signal SM; flip-flops (FFs) 30, 31 and 32; selectors 50, 51 and 52 controlled by a test mode signal TEST; logic sections 80 and 81; and a RAM 91.

In FIG. 12, the selectors 10, 11 and 12 and flip-flops 30, 31 and 32 constitute a scan path. The scan path is a memory circuit including parallel paths across the outputs of the logic section 80 and the inputs of the RAM 91, and a serial shift path for serially transmitting data from an SI (scan-in) terminal to an SO (scan-out) terminal.

Next, the operation of the semiconductor integrated circuit device as shown in FIG. 12 will be described.

In a normal operation mode, the selectors 10, 11 and 12 are switched to their “0” input terminals by placing a shift mode signal at SM=0, and the selectors 50, 51 and 52 are switched to their “0” input terminals by placing a test mode signal at TEST=0. Thus, the data output from the logic section 80 are selected by the selectors 10, 11 and 12 to be supplied to the input terminals DI0, DI1 and DI2 of the RAM 91 via the flip-flops 30, 31 and 32. Although not shown in this figure, the flip-flops 30, 31 and 32 are supplied with a clock signal. In addition, the data from the output terminals DO0, DO1 and DO2 of the RAM 91 are selected by the selectors 50, 51 and 52 to be delivered to the logic section 81. In this way, in the normal operation mode, the data write and read are carried out under the condition that the RAM 91 is interposed between the logic sections 80 and 81.

In the scan test mode of the logic sections 80 and 81, the selectors 50, 51 and 52 are switched to the “1” input terminals by placing the test mode signal at TEST=1. In this state, the selectors 50, 51 and 52 select and output the data fed to the “1” input terminals. Accordingly, the RAM 91 is bypassed under the condition that the scan path is interposed between the logic section 80 and logic section 81. In this state, the scan test of the logic sections 80 and 81 is carried out with controlling the shift mode signal SM.

In the scan test mode of the logic section 81, the selectors 10, 11 and 12 are switched to the “1” input terminals by placing the shift mode signal at SM=l so that they select the data fed to the “1” input terminals. Accordingly, when the flip-flops 30, 31 and 32 are supplied with three clock pulses, 3-bit test data fed to the SI terminal are shifted serially and stored in the flip-flops 30, 31 and 32. Since the test mode signal TEST=1 in this case, the 3-bit test data stored in the flip-flops 30, 31 and 32 are supplied to the logic section 81. Thus, the scan test of the logic section 81 is carried out by checking the data the logic section 81 outputs.

In the scan test mode of the logic section 80, the selectors 10, 11 and 12 are switched to the “0” input terminals by placing the shift mode signal at SM=0 so that they select the 3-bit data output from the logic section 80, which has received test data and carried out specified operation. Receiving one clock pulse, the flip-flops 30, 31 and 32 store the 3-bit data fed from the logic section 80. The 1-bit data stored in the flip-flop 32 is output from the SO terminal. Subsequently, the selectors 10, 11 and 12 are switched to the “1” input terminals by placing the shift mode signal at SM=1. Then, supplying the flip-flops 30, 31 and 32 with two clock pulses causes the 1-bit data stored in the flip-flops 30 and 31 to be shifted and output serially from the SO terminal, thereby implementing the scan test of the logic section 80.

The semiconductor integrated circuit device as shown in FIG. 12 can set the test data from the SI terminal to the input terminals DI0, DI1 and DI2 of the RAM 91 by the serial shift operation while the shift mode signal SM=1. However, it cannot load the data output from the output terminals DO0, DO1 and DO2 of the RAM 91 onto the flip-flops 30, 31 and 32 to output the data from the SO terminal. Consequently, it cannot carry out the test of the RAM 91 in isolation.

FIG. 13 is a circuit diagram showing a configuration of a conventional semiconductor integrated circuit device with the test function of the RAM 91 in isolation, which is disclosed in the Relevant Reference 1. To carry out the test of the RAM 91, it includes, in addition to the semiconductor integrated circuit device as shown in FIG. 12, selectors 60, 61 and 62 controlled by an output selecting signal SELDO, and selectors 70, 71 and 72 controlled by a RAM test signal RAMTEST.

The selectors 60, 61 and 62 have their “1” input terminals supplied with the data from the output terminals DO0, DO1 and DO2 of the RAM 91. The selector 60 has its “0” input terminal supplied with the test data from the SI terminal, and selectors 61 and 62 have their “0” input terminals supplied with the data from the flip-flops 30 and 31, respectively. On the other hand, the selectors 70, 71 and 72 have their “0” input terminals supplied with the data from the flip-flops 30, 31 and 32, and have their “1” input terminals with the RAM test data from the SID terminal.

Next, the operation of the semiconductor integrated circuit device as shown in FIG. 13 will be described.

In the normal operation mode, the selectors 10, 11 and 12 are switched to their “0” input terminals by placing the shift mode signal at SM=0, the selectors 50, 51 and 52 are switched to their “0” input terminals by placing the test mode signal at TEST=0, and the selectors 70, 71 and 72 are switched to their “0” input terminals by placing the RAM test signal at RAMTEST=0. In this state, the data output from the logic section 80 are supplied to the input terminals DI0, DI1 and DI2 of the RAM 91 via the flip-flops 30, 31 and 32. The flip-flops 30, 31 and 32 are fed with the clock signal. The data from the output terminals DO0, DO1 and DO2 of the RAM 91 are transferred to the logic 81. Thus, in the normal operation mode, the data are written and read in the condition that the RAM 91 is interposed between the logic sections 80 and 81.

In the scan test mode of the logic sections 80 and 81, the selectors 50, 51 and 52 are switched to their “1” input terminals by placing the test mode signal at TEST=1, and the selectors 60, 61 and 62 are switched to their “0” input terminals by placing the output selecting signal at SELDO=0. Thus, the RAM 91 and the scan path are place in the condition that the RAM 91 is bypassed, and the scan path is interposed between the logic sections 80 and 81. In this state, the logic sections 80 and 81 are subjected to the scan test by controlling the shift mode signal SM in the same manner as the semiconductor integrated circuit device as shown in FIG. 12.

To test the RAM 91, the selectors 70, 71 and 72 are switched to their “1” input terminals by placing the RAM test signal at RAMTEST=1 so that the RAM test data from the SID terminal is supplied to the RAM 91 as the write data. Here, the 1-bit RAM test data is supplied to the RAM 91 in common as the 3-bit write data. In other words, the write data such as “000” or “111” are simultaneously supplied to the RAM 91.

The selectors 60, 61 and 62 controlled by the output selecting signal SELDO are provided for the purpose of loading the test result data from the output terminals DO0-DO2 of the RAM 91 onto the scan path. When the selectors 60, 61 and 62 are switched to their “1” input terminals by placing the output selecting signal at SELDO=1, and the selectors 10, 11 and 12 are switched to their “1” input terminals by placing the shift mode signal at SM=1, a clock pulse applied to the flip-flops 30, 31 and 32 causes them to store the test result data from the output terminals DO0-DO2 of the RAM 91. In this case, the 1-bit data stored in the flip-flop 32 is output from the SO terminal. Subsequently, the selectors 60, 61 and 62 are switched to their “0” input terminals by placing the output selecting signal SELDO=0, and two clock pulses are applied to the flip-flops 30, 31 and 32. Thus, the 1-bit data stored in the flip-flops 30 and 31 are read out of the SO terminal by the serial shift operation. Thus, a test device outside the chip or a self-test circuit inside the chip makes a fault decision.

Relevant Reference 1: U.S. Pat. No. 5,960,008 (particularly, from column 5, line 12 to column 7, line 59).

With the foregoing configuration, the conventional semiconductor integrated circuit device as shown in FIG. 12 has a problem of being unable to carry out the test of the functional block such as the RAM 91 in isolation. In addition, the circuit as shown in FIG. 13 has a problem in that the scale of the test circuit of the functional block such as the RAM 91 inevitably increases.

### SUMMARY OF THE INVENTION

The present invention is implemented to solve the foregoing problems. It is therefore an object of the present invention to provide a semiconductor integrated circuit device capable of carrying out the test of the functional block such as the RAM 91 in isolation without increasing the scale of the test circuit.

According to one aspect of the present invention, there is provided a plurality of second selectors interposed into a serial shift path of a scan path, for connecting one of a set of outputs of a functional block and a set of outputs of the serial shift path to the inputs of a second logic section. The test data from the serial shift path of the scan path are shifted into the functional block via the second selectors and first selectors, and test result data the functional block produces are output from the serial shift path of the scan path via the second selectors after switching the second selectors. It can test the functional block in isolation without increasing the scale of the test circuit.

### BRIEF DESCRIPTION OF THE DRAWINGS

FIG. 1 is a circuit diagram showing a configuration of an embodiment 1 of the semiconductor integrated circuit device in accordance with the present invention;

FIG. 2 is a circuit diagram showing a configuration of an embodiment 2 of the semiconductor integrated circuit device in accordance with the present invention;

FIG. 3 is a circuit diagram showing a configuration of an embodiment 3 of the semiconductor integrated circuit device in accordance with the present invention;

FIG. 4 is a circuit diagram showing a configuration of an embodiment 4 of the semiconductor integrated circuit device in accordance with the present invention;

FIG. 5 is a circuit diagram showing a configuration of an embodiment 5 of the semiconductor integrated circuit device in accordance with the present invention;

FIG. 6 is a circuit diagram showing a configuration of an embodiment 6 of the semiconductor integrated circuit device in accordance with the present invention;

FIG. 7 is a circuit diagram showing a configuration of an embodiment 7 of the semiconductor integrated circuit device in accordance with the present invention;

FIG. 8 is a circuit diagram showing a configuration of an embodiment 8 of the semiconductor integrated circuit device in accordance with the present invention;

FIG. 9 is a circuit diagram showing a configuration of an embodiment 9 of the semiconductor integrated circuit device in accordance with the present invention;

FIG. 10 is a circuit diagram showing a configuration of an embodiment 10 of the semiconductor integrated circuit device in accordance with the present invention;

FIG. 11 is a circuit diagram showing a configuration of an embodiment 11 of the semiconductor integrated circuit device in accordance with the present invention;

FIG. 12 is a circuit diagram showing a configuration of a conventional semiconductor integrated circuit device; and

FIG. 13 is a circuit diagram showing another configuration of a conventional semiconductor integrated circuit device.

### DETAILED DESCRIPTION OF THE PREFERRED EMBODIMENTS

The invention will now be described with reference to the accompanying drawings.

### Embodiment 1

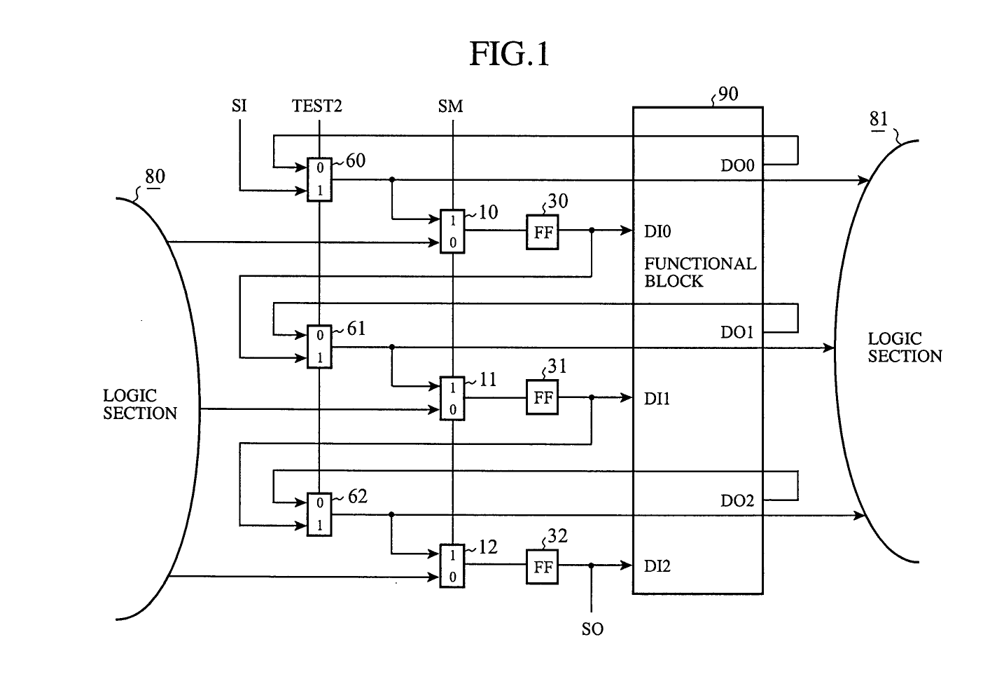

FIG. 1 is a circuit diagram showing a configuration of an embodiment 1 of the semiconductor integrated circuit device in accordance with the present invention. As shown in FIG. 1, the semiconductor integrated circuit device comprises selectors 10, 11 and 12 (first selectors) controlled by a shift mode signal SM; flip-flops (FFs) 30, 31 and 32; selectors 60, 61 and 62 (second selectors) controlled by a test mode signal TEST2; a logic section 80 (first logic section); a logic section 81 (second logic section); and a functional block 90. The functional block 90 can include, besides a RAM, various logical functional blocks such as a computing circuit, interface circuit, and memory block.

In FIG. 1, the selectors 60, 61 and 62, selectors 10, 11 and 12 and flip-flops 30, 31 and 32 constitute a scan path. The scan path is memory circuit including parallel paths across the outputs of the logic section 80 and the inputs of the functional block 90, and a serial shift path for serially transmitting data from an SI (scan-in) terminal to an SO (scan-out) terminal. The selectors 60, 61 and 62 are inserted into the serial shift path of the scan path.

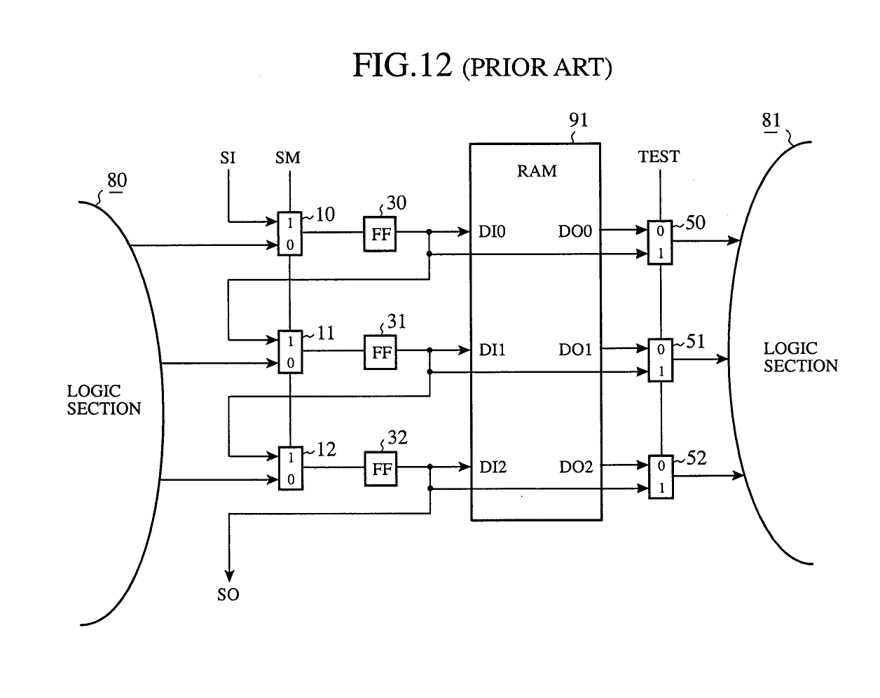

In FIG. 1, the selectors 60, 61 and 62, which are interposed in positions different from those of the selectors 50, 51 and 52 of the conventional device of FIG. 12, supply the data output from the output terminals DO0, DO1 and DO2 of the functional block 90 to the scan path. This enables the test of the functional block 90 in isolation without increasing the scale of the test circuit.

Next, the operation of the present embodiment 1 will be described.

In the normal operation mode, the selectors 10, 11 and 12 are switched to their “0” input terminals by placing the shift mode signal at SM=0, and selectors 60, 61 and 62 are also switched to their “0” input terminals by placing the test mode signal at TEST2=0. In this state, the data output from the logic section 80 are selected by the selectors 10, 11 and 12 to be supplied to the input terminals DI0, DI1 and DI2 of the functional block 90 via the flip-flops 30, 31 and 32. Here, the flip-flops 30, 31 and 32 are supplied with the clock signal.

In addition, the data from the output terminals DO0, DO1 and DO2 of the functional block 90 are selected by the selectors 60, 61 and 62 to be delivered to the logic section 81. In this way, in the normal operation mode, specified computations and data processing are carried out under the condition that the functional block 90 is interposed between the logic sections 80 and 81.

In the scan test mode of the logic sections 80 and 81, the selectors 60, 61 and 62 are switched to their “1” input terminals by placing the test mode signal at TEST2=1. In this state, the functional block 90 is bypassed, and the scan path is interposed between the logic sections 80 and 81. The scan test of the logic sections 80 and 81 is carried out with controlling the shift mode signal SM.

In the scan test mode of the logic section 81, the selectors 10, 11 and 12 are switched to their “1” input terminals by placing the shift mode signal at SM=1. Accordingly, supplying two clock pulses to the flip-flops 30, 31 and 32 causes the 2-bit test data from the SI terminal to be shifted serially and stored into the flip-flops 30 and 31.

Since the test mode signal is placed at TEST2=1, the 1-bit test data next to the SI terminal is selected by the selector 60 and input to the logic section 81. Likewise, the individual 1-bit test data stored in the flip-flops 30 and 31 are selected by the selectors 61 and 62 and input to the logic section 81. Thus, the total of 3-bit test data carry out the scan test of the logic section 81.

In the scan test mode of the logic section 80, the selectors 10, 11 and 12 are switched to their “0” input terminals by placing the shift mode signal at SM=0. Receiving one clock pulse, the flip-flops 30, 31 and 32 store the 3-bit data output as the test result from the logic section 80 that has input the test data. In this case, the 1-bit data stored in the flip-flop 32 is output from the SO terminal.

Subsequently, the selectors 10, 11 and 12 are switched to their “1” input terminals by placing the shift mode signal at SM=1. Then, supplying the flip-flops 30, 31 and 32 with two clock pulses causes the individual 1-bit data stored in the flip-flops 30 and 31 to be shifted and output serially from the SO terminal, thereby enabling confirming the contents of the total of 3-bit data. In this case, the next test data for the logic section 81 can be stored in the flip-flops 30 and 31 via the SI terminal. The scan test of the logic sections 80 and 81 is repeated a plurality of times with changing the input test data.

To carry out the test of the functional block 90, the selectors 10, 11 and 12 are switched to their “1” input terminals by placing the shift mode signal at SM=1. Then, the selectors 60, 61 and 62 are switched to their “1” input terminals by placing the test mode signal at TEST2=1. In this state, supplying three clock pulses to the flip-flops 30, 31 and 32 causes the 3-bit test data to be serially shifted from the SI terminal to the flip-flops 30, 31 and 32. Then, they are input to the input terminals DI0, DI1 and DI2 of the functional block 90. The functional block 90 carries out the specified operation, and the test result data are output from the output terminals DO0, DO1 and DO2.

Next, the selectors 60, 61 and 62 are switched to their “0” input terminals by placing the test mode signal at TEST2=0. Supplying one clock pulse to the flip-flops 30, 31 and 32 causes them to store the test result data output from the output terminals DO0, DO1 and DO2 of the functional block 90. In this case, the 1-bit data stored in the flip-flop 32 is output from the SO terminal.

Subsequently, the selectors 60, 61 and 62 are switched to their “1” input terminals by placing the test mode signal at TEST2=1. Supplying two clock pulses to the flip-flops 30, 31 and 32 causes the individual 1-bit data stored in them to be shifted out from the SO terminal, thereby making it possible to confirm the contents of the total of 3-bit data. The test of the functional block 90 is repeated a plurality of times with changing the test data input from the SI terminal.

As described above, the present embodiment 1 offers an advantage of being able to test the functional block 90 in isolation without increasing the scale of the test circuit.

### Embodiment 2

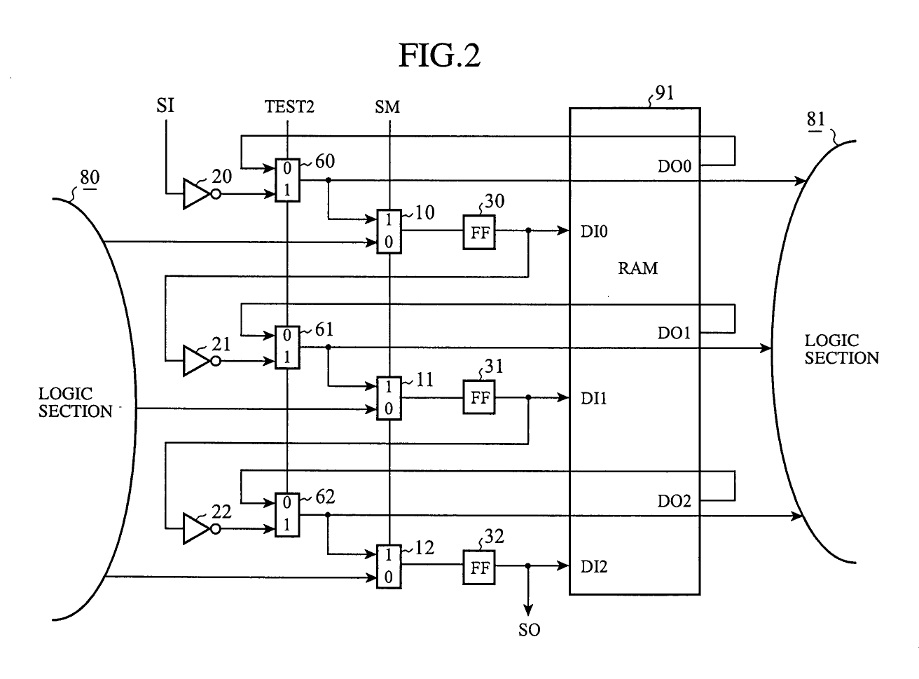

FIG. 2 is a circuit diagram showing a configuration of an embodiment 2 of the semiconductor integrated circuit device in accordance with the present invention. As shown in FIG. 2, the present embodiment 2 replaces the functional block 90 of the foregoing embodiment 1 of FIG. 1 by a RAM 91, and interposes inverters 20, 21 and 22 into the serial shift path of the scan path. The inverters 20, 21 and 22 enable the test data to be written into the RAM 91 to be switched between all zero (“000”) and all one (“111”) at one clock cycle. Thus, the present embodiment 2 can easily carry out the test of the RAM 91 in such a manner that it writes “000” and then “111” in the next cycle, or writes “111” and then “000” in the next cycle.

Next, the operation of the present embodiment 2 will be described.

The normal operation is the same as that of the foregoing embodiment 1 except that the functional block 90 of the embodiment 1 is replaced by the RAM 91. In this case, the inverters 20, 21 and 22 are unrelated to the operation. The scan test of the logic sections 80 and 81 is basically the same as that of the embodiment 1 except that the test data and test result data are inverted or non-inverted through the inverters 20, 21 and 22.

First, the test of the RAM 91 will be described.

A write test of the initial data to the RAM 91 will be described first. The selectors 10, 11 and 12 are switched to their “1” input terminals by placing the shift mode signal at SM=1, and the selectors 60, 61 and 62 are switched to their “1” input terminals by placing the test mode signal at TEST2=1. Supplying three clock pulses to the flip-flops 30, 31 and 32 causes them to store the 3-bit test data fed from the SI terminal by the serial shift operation. It must be considered in this case that the flip-flops 30 and 32 store the test data inverted by the inverters 20, 21 and 22. For example, when the test data “010” is shifted in from the SI terminal, the flip-flops 30, 31 and 32 output the test data “111”, which is supplied to the input terminals DI0, DI1 and DI2 of the RAM 91.

When successive test data “101010 . . . ” are shifted in from the SI terminal, the input terminals DI0, DI1 and DI2 of the RAM 91 are supplied with the test data alternating between “111” and “000”. When desired test data “111” or “000” are placed, the data is written to the RAM 91. Thus, the test data to be written into the RAM 91 can be switched between all zero (“000”) and all one (“111”) at one clock cycle. The test data write to the RAM 91 is repeated a plurality of times with changing the addresses.

Next, a read test from specified addresses of the RAM 91 will be described. The selectors 10, 11 and 12 are switched to their “1” input terminals by placing the shift mode signal at SM=1, whereas the selectors 60, 61 and 62 are switched to their “0” input terminals by placing the test mode signal at TEST2=0. The read test from specified addresses of the RAM 91 causes the test result data to be output from the output terminals DO0, DO1 and DO2 of the RAM 91, and then from the selectors 10, 11 and 12 via the selectors 60, 61 and 62. Supplying one clock pulse to the flip-flops 30, 31 and 32 causes them to store the test result data. In this case, the 1-bit data stored in the flip-flop 32 is output to the SO terminal.

Subsequently, the selectors 60, 61 and 62 are switched to their “1” input terminals by placing the test mode signal at TEST2=1. Supplying two clock pulses to the flip-flops 30, 31 and 32 causes the individual 1-bit data stored in the flip-flops 30 and 31 to be shifted out of the SO terminal by the serial shift operation, making it possible to confirm the contents of the total of 3-bit data. It must be considered in the test, however, that the data stored in the flip-flop 30 passes through the inverters 21 and 22, and the data stored in the flip-flop 31 passes through the inverter 22 before serially output from the SO terminal. The read test of the RAM 91 is repeated a plurality of times with changing the addresses.

The inverter 20 may be omitted when the test data to be shifted in from the SI terminal is inverted.

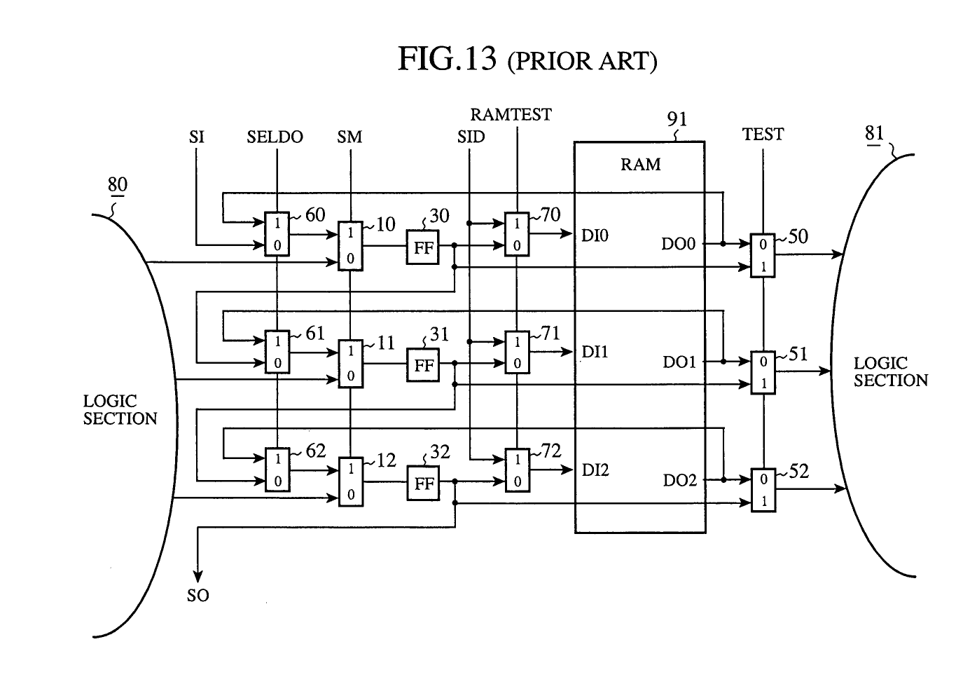

Comparing the present embodiment 2 with the conventional device of FIG. 13, it is obvious that the present embodiment 2 can eliminate the selectors 50, 51 and 52 and selectors 70, 71 and 72 of FIG. 13.

As described above, the present embodiment 2 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently.

### Embodiment 3

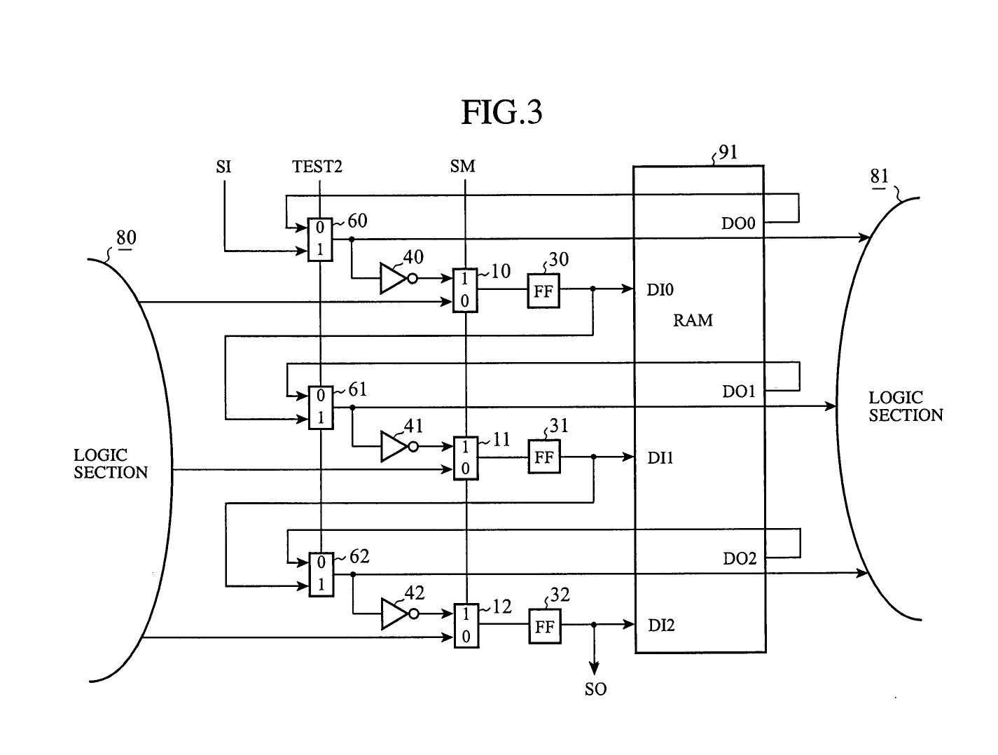

FIG. 3 is a circuit diagram showing a configuration of an embodiment 3 of the semiconductor integrated circuit device in accordance with the present invention. As shown in FIG. 3, the present embodiment 3 has inverters 40, 41 and 42 interposed into the serial shift path of the scan path, instead of the inverters 20, 21 and 22 of the foregoing embodiment 2 of FIG. 2. Using the inverters 40, 41 and 42 makes it possible to switch the test data to be written into the RAM 91 between all zero (“000”) and all one (“111”) at one clock cycle.

Next, the operation of the present embodiment 3 will be described.

The normal operation is the same as that of the foregoing embodiment 1 except that the functional block 90 of the embodiment 1 is replaced by the RAM 91, with the inverters 40, 41 and 42 being unrelated to the operation. The scan test of the logic sections 80 and 81 is basically the same as that of the embodiment 1 except that the test data and test result data are inverted or non-inverted through the inverters 40, 41 and 42.

First, the test of the RAM 91 will be described.

A write test of the initial data to the RAM 91 will be described first. The selectors 10, 11 and 12 are switched to their “1” input terminals by placing the shift mode signal at SM=1, and the selectors 60, 61 and 62 are switched to their “1” input terminals by placing the test mode signal at TEST2=1. Supplying three clock pulses to the flip-flops 30, 31 and 32 causes them to store the 3-bit test data fed from the SI terminal by the serial shift operation. It must be considered in this case that the flip-flops 30 and 32 store the test data inverted by the inverters 40, 41 and 42. For example, when the test data “010” is shifted in from the SI terminal, the flip-flops 30, 31 and 32 output the test data “111”, which are supplied to the input terminals DI0, DI1 and DI2 of the RAM 91.

When successive test data “101010 . . . ” is shifted in from the SI terminal, the input terminals DI0, DI1 and DI2 of the RAM 91 are supplied with the test data alternating between “111” and “000”. When desired test data “111” or “000” are placed, the data are written to the RAM 91. Thus, the test data to be written into the RAM 91 can be switched between all zero (“000”) and all one (“111”) at one clock cycle. The test data write to the RAM 91 is repeated a plurality of times with changing the addresses.

Next, a read and write test from and to specified addresses of the RAM 91 will be described. The selectors 10, 11 and 12 are switched to their “1” input terminals by placing the shift mode signal at SM=1, whereas the selectors 60, 61 and 62 are switched to their “0” input terminals by placing the test mode signal at TEST2=0. The read test from specified addresses of the RAM 91 causes the test result data to be output from the output terminals DO0, DO1 and DO2 of the RAM 91, and then from the selectors 10, 11 and 12 via the selectors 60, 61 and 62 and the inverters 40, 41 and 42 that invert the test result data. Supplying one clock pulse to the flip-flops 30, 31 and 32 causes them to store the test result data. In this case, the 1-bit data stored in the flip-flop 32 is output from the SO terminal.

Subsequently, the inverted test result data stored in the flip-flops 30, 31 and 32 is supplied to the input terminals DI0, DI1 and DI2 of the RAM 91 so that the inverted test result data is written into the RAM 91. For example, when the test result data output from the output terminals DO0, DO1 and DO2 of the RAM 91 is “000”, the inverted test data “111” is written into the RAM 91 in the next cycle.

Subsequently, the selectors 60, 61 and 62 are switched to their “1” input terminals by placing the test mode signal at TEST2=1. Supplying two clock pulses to the flip-flops 30, 31 and 32 causes the individual 1-bit data stored in the flip-flops 30 and 31 to be shifted out of the SO terminal, making it possible to confirm the contents of the total of 3-bit data. It must be considered in the test, however, that the data stored in the flip-flop 30 passes through the inverters 41 and 42, and the data stored in the flip-flop 31 passes through the inverter 42 before serially output from the SO terminal. The read and write test of the RAM 91 is repeated a plurality of times with changing the addresses.

As described above, the present embodiment 3 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently.

### Embodiment 4

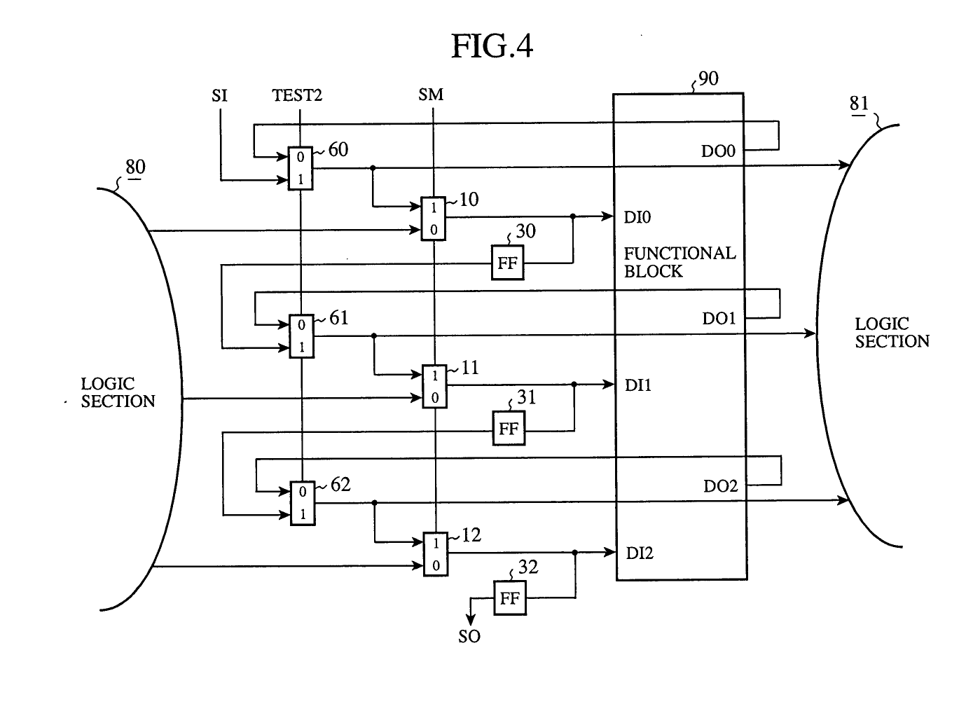

FIG. 4 is a circuit diagram showing a configuration of an embodiment 4 of the semiconductor integrated circuit device in accordance with the present invention. Although the input terminals DI0, DI1 and DI2 of the functional block 90 are supplied with the outputs of the flip-flops 30, 31 and 32 in the foregoing embodiment 1 of FIG. 1, they are supplied with the outputs of the selectors 10, 11 and 12 in the present embodiment 4 as shown in FIG. 4.

Next, the operation of the present embodiment 4 will be described.

In the normal operation mode, the selectors 10, 11 and 12 are switched to their “0” input terminals by placing the shift mode signal at SM=0, and the selectors 60, 61 and 62 are switched to their “0” input terminals by placing the test mode signal at TEST2=0. The data output from the logic section 80 are selected by the selectors 10, 11 and 12 to be directly supplied to the input terminals DI0, DI1 and DI2 of the functional block 90.

In addition, the data from the output terminals DO0, DO1 and DO2 of the functional block 90 are selected by the selectors 60, 61 and 62 to be delivered to the logic section 81. In this way, in the normal operation mode, specified computations and data processing are carried out under the condition that the functional block 90 is interposed between the logic sections 80 and 81. In the present embodiment 4, the flip-flops 30, 31 and 32 have nothing to do with the normal operation mode. Thus, it is not necessary in the normal operation mode to supply the flip-flops 30, 31 and 32 with the clock signal.

As for the scan test of the logic sections 80 and 81, it is the same as that of the foregoing embodiment 1 of FIG. 1. This is because the positions of the flip-flops 30, 31 and 32 in the serial shift path of the scan path are the same in both the embodiments 1 and 4.

To carry out the test of the functional block 90, the selectors 10, 11 and 12 are switched to their “1” input terminals by placing the shift mode signal at SM=1. Then, the selectors 60, 61 and 62 are switched to their “1” input terminals by placing the test mode signal at TEST2=1. In this state, supplying two clock pulses to the flip-flops 30, 31 and 32 causes the 2-bit test data to be serially shifted from the SI terminal to the flip-flops 30 and 31.

The next 1-bit test data input to the SI terminal is selected by the selectors 60 and 10, and supplied to the input terminal DI0 of the functional block 90. On the other hand, the individual 1-bit test data stored in the flip-flops 30 and 31 are selected by the selectors 61 and 62 and selectors 11 and 12, and supplied to the input terminals DI1 and DI2 of the functional block 90. The functional block 90 carries out the prescribed operation, and the test result data are output from the output terminals DO0, DO1 and DO2 of the functional block 90.

Next, the selectors 60, 61 and 62 are switched to their “0” input terminals by placing the test mode signal at TEST2=0. Supplying one clock pulse to the flip-flops 30, 31 and 32 causes them to store the test result data output from the output terminals DO0, DO1 and DO2 of the functional block 90. In this case, the 1-bit data stored in the flip-flop 32 is output from the SO terminal.

Subsequently, the selectors 60, 61 and 62 are switched to their “1” input terminals by placing the test mode signal at TEST2=1. Supplying two clock pulses to the flip-flops 30, 31 and 32 causes the individual 1-bit data stored in them to be shifted out of the SO terminal, thereby making it possible to confirm the contents of the total of 3-bit data. The test of the functional block 90 is repeated a plurality of times with changing the test data input from the SI terminal.

As described above, the present embodiment 4 offers an advantage of being able to test the functional block 90 in isolation without increasing the scale of the test circuit. In addition, it offers an advantage of being able to carry out the normal operation mode without supplying the flip-flops 30, 31 and 32 with the clock signal.

### Embodiment 5

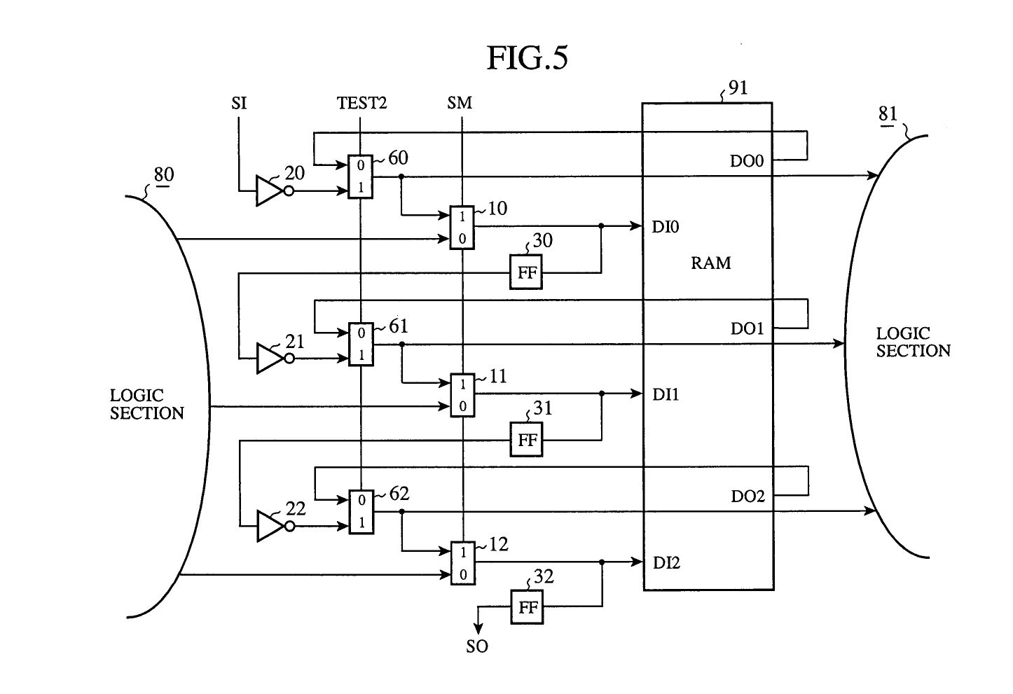

FIG. 5 is a circuit diagram showing a configuration of an embodiment 5 of the semiconductor integrated circuit device in accordance with the present invention. Although the input terminals DI0, DI1 and DI2 of the RAM 91 are supplied with the output of the flip-flops 30, 31 and 32 in the foregoing embodiment 2 of FIG. 2, they are supplied with the output of the selectors 10, 11 and 12 in the present embodiment 5 as shown in FIG. 5.

Next, the operation of the present embodiment 5 will be described.

The normal operation is the same as that of the foregoing embodiment 4 except that the functional block 90 of the embodiment 4 is replaced by the RAM 91, with the inverters 20, 21 and 22 and flip-flops 30, 31 and 32 having nothing to do with the normal operation. Thus, it is unnecessary for the flip-flops 30, 31 and 32 to be supplied with the clock signal. The scan test of the logic sections 80 and 81 is basically the same as that of the embodiment 4 except that the test data and test result data are inverted or non-inverted through the inverters 20, 21 and 22.

The test of the RAM 91 will be described.

First, a write test of the initial data to the RAM 91 will be described. The selectors 10, 11 and 12 are switched to their “1” input terminals by placing the shift mode signal at SM=1, and the selectors 60, 61 and 62 are switched to their “1” input terminals by placing the test mode signal at TEST2=1. Supplying two clock pulses to the flip-flops 30, 31 and 32 causes the flip-flops 30 and 31 to store the 2-bit test data fed from the SI terminal by the serial shift operation.

In this case, the flip-flop 30 stores the inverted test data. Accordingly, when the data “10” is shifted in from the SI terminal, the outputs of the flip-flops 30 and 31 become “11”. The output of the flip-flop 30 is supplied to the input terminal DI1 of the RAM 91 via the inverter 21, and the output of the flip-flop 31 is supplied to the input terminal DI2 of the RAM 91 via the inverter 22. Thus, the input terminals DI1 and DI2 of the RAM 91 are supplied with the test data “00”. When the successive test data “1” is supplied from the SI terminal to the input terminal DI0 of the RAM 91 via the inverter 20, the test data supplied to the input terminals DI0, DI1 and DI2 of the RAM 91 become “000”.

When successive test data “101010 . . . ”, in which the first bit “1” is the foregoing test data, is shifted in from the SI terminal, the input terminals DI0, DI1 and DI2 of the RAM 91 are supplied with the test data alternating between “111” and “000”. When desired test data “111” or “000” are placed, the data are written to the RAM 91. Thus, the test data to be written into the RAM 91 can be switched between all zero (“000”) and all one (“111”) at one clock cycle. The test data write to the RAM 91 is repeated a plurality of times with changing the addresses.

As for the read test from specified addresses of the RAM 91, it is the same as that of the foregoing embodiment 2. The inverter 20 can be omitted as in the embodiment 2.

As described above, the present embodiment 5 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently. Furthermore, it offers an advantage of being able to carry out the normal operation mode without supplying the flip-flops 30, 31 and 32 with the clock signal.

### Embodiment 6

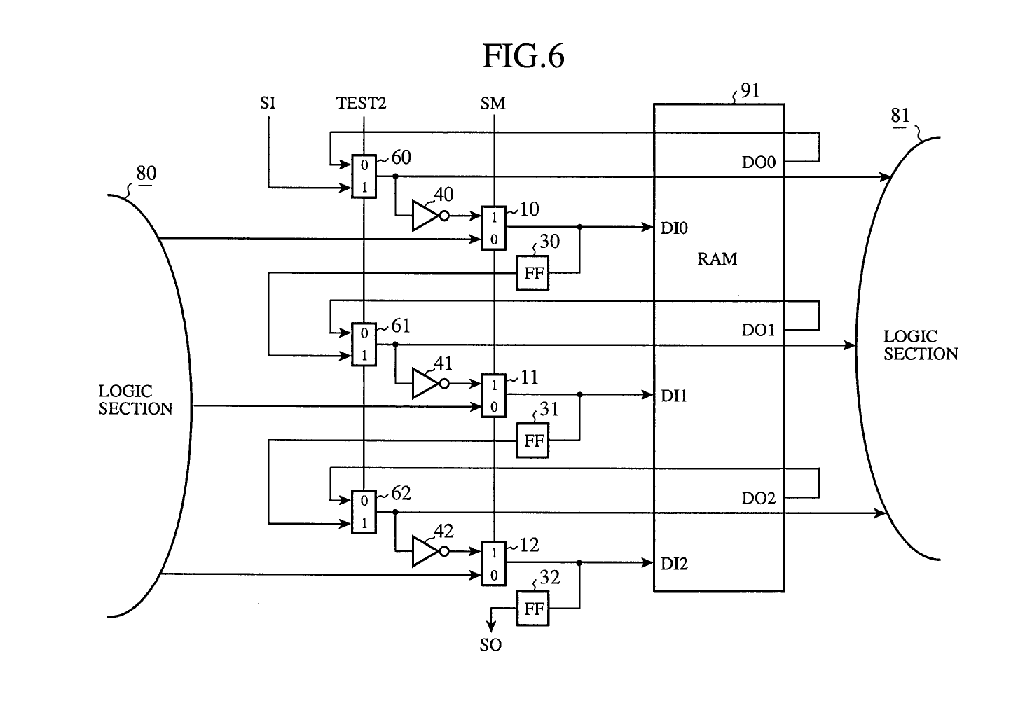

FIG. 6 is a circuit diagram showing a configuration of an embodiment 6 of the semiconductor integrated circuit device in accordance with the present invention. Although the input terminals DI0, DI1 and DI2 of the RAM 91 are supplied with the outputs of the flip-flops 30, 31 and 32 in the foregoing embodiment 3 of FIG. 3, they are supplied with the outputs of the selectors 10, 11 and 12 in the present embodiment 6 as shown in FIG. 6.

Next, the operation of the present embodiment 6 will be described.

The normal operation is the same as that of the foregoing embodiment 4 except that the functional block 90 of the embodiment 4 is replaced by the RAM 91, and the inverters 40, 41 and 42 and flip-flops 30, 31 and 32 have nothing to do with the normal operation. Thus, it is unnecessary for the flip-flops 30, 31 and 32 to be supplied with the clock signal. The scan test of the logic sections 80 and 81 is basically the same as that of the embodiment 4 except that the test data and test result data are inverted or non-inverted through the inverters 40, 41 and 42.

The test of the RAM 91 will be described. A write test of the initial data to the RAM 91 is the same as that of the foregoing embodiment 5 except that the inverters 20, 21 and 22 are replaced with the inverters 40, 41 and 42.

Next, a read and write test from and to specified addresses of the RAM 91 will be described. The selectors 10, 11 and 12 are switched to their “1” input terminals by placing the shift mode signal at SM=1, whereas the selectors 60, 61 and 62 are switched to their “0” input terminals by placing the test mode signal at TEST2=0. The read test from specified addresses of the RAM 91 causes the test result data to be output from the output terminals DO0, DO1 and DO2 of the RAM 91, and then from the selectors 10, 11 and 12 via the selectors 60, 61 and 62 and the inverters 40, 41 and 42 that invert the test result data.

Subsequently, the inverted test result data output from the selectors 10, 11 and 12 are supplied to the input terminals DI0, DI1 and DI2 of the RAM 91 so that the inverted test result data are written into the RAM 91. For example, when the test result data output from the output terminals DO0, DO1 and DO2 of the RAM 91 are “000”, the inverted test data “111” are written into the RAM 91 in the next cycle.

Supplying one clock pulse to the flip-flops 30, 31 and 32 causes them to store the inverted test result data output from the selectors 10, 11 and 12. In this case, the 1-bit data stored in the flip-flop 32 is output from the SO terminal.

Subsequently, the selectors 60, 61 and 62 are switched to their “1” input terminals by placing the test mode signal at TEST2=1. Supplying two clock pulses to the flip-flops 30, 31 and 32 causes the individual 1-bit data stored in the flip-flops 30 and 31 to be shifted out from the SO terminal, making it possible to confirm the contents of the total of 3-bit data. It must be considered in the test, however, that the data stored in the flip-flop 30 passes through the inverters 41 and 42, and the data stored in the flip-flop 31 passes through the inverter 42 before serially output from the SO terminal. The read and write test of the RAM 91 is repeated a plurality of times with changing the addresses.

As described above, the present embodiment 6 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently. Furthermore, it offers an advantage of being able to carry out the normal operation mode without supplying the flip-flops 30, 31 and 32 with the clock signal.

### Embodiment 7

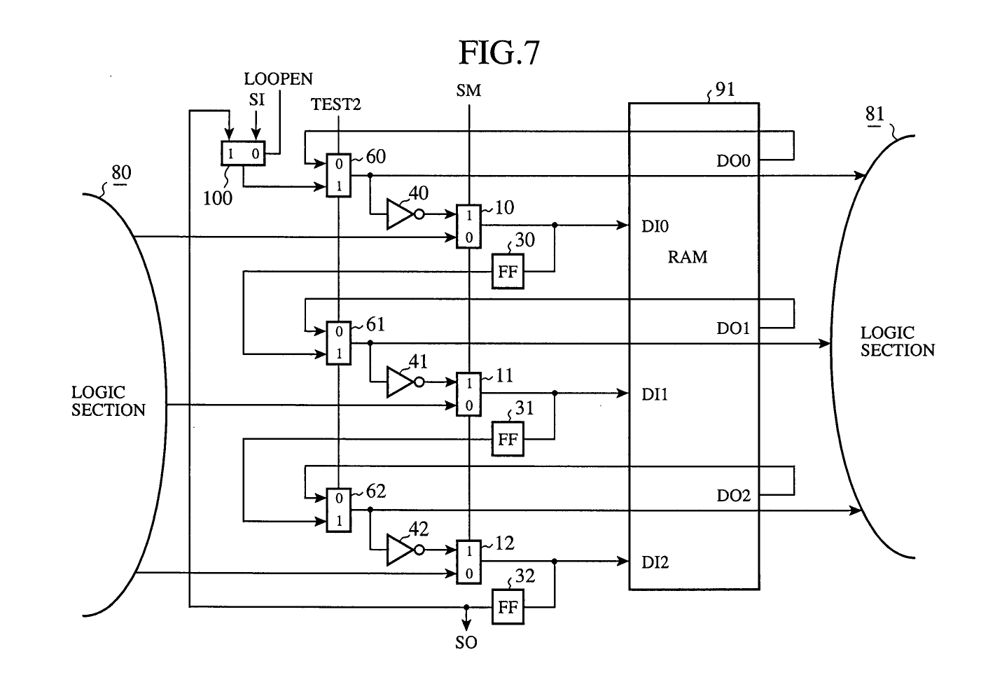

FIG. 7 is a circuit diagram showing a configuration of an embodiment 7 of the semiconductor integrated circuit device in accordance with the present invention. As shown in FIG. 7, the present embodiment 7 has a selector 100 (third selector) for feeding the data supplied to the SO terminal back to the SI terminal in addition to the foregoing embodiment 6 of FIG. 6. The selector 100 is controlled by a loop enabling signal LOOPEN. The selector 100 can also be added to the embodiment 2 of FIG. 2, embodiment 3 of FIG. 3, and embodiment 5 of FIG. 5.

Next, the operation of the present embodiment 7 will be described.

In the normal operation mode, the selectors 10, 11 and 12 are switched to their “0” input terminals by placing the shift mode signal at SM=0, and the selectors 60, 61 and 62 are switched to their “0” input terminals by placing the test mode signal at TEST2=0. The inverters 40, 41 and 42 and flip-flops 30, 31 and 32 are unrelated to the normal operation mode, so that the normal operation is carried out as in the foregoing embodiment 4 except that the functional block 90 of the embodiment 4 is changed to the RAM 91. Thus, the flip-flops 30, 31 and 32 need not be supplied with the clock signal.

To carry out the scan test of the logic sections 80 and 81, the selector 100 is switched to its “0” input terminal by placing the loop enabling signal at LOOPEN=0, and the selectors 60, 61 and 62 are switched to their “1” input terminals by placing the test mode signal at TEST2=1. The scan test of the logic sections 80 and 81 is basically the same as that of the embodiment 4, in which it should be considered that the test data and test result data are inverted or non-inverted through the inverters 40, 41 and 42.

Next, the test of the RAM 91 will be described.

First, a write test of the initial data to the RAM 91 will be described. The selector 100 is switched to its “0” input terminal by placing the loop enabling signal at LOOPEN=0, the selectors 10, 11 and 12 are switched to their “1” input terminals by placing the shift mode signal at SM=1, and the selectors 60, 61 and 62 are switched to their “1” input terminals by placing the test mode signal at TEST2=1.

Supplying three clock pulses to the flip-flops 30, 31 and 32 causes them to store the 3-bit test data fed from the SI terminal by the serial shift operation. It must be considered in this case that the flip-flops 30 and 32 store the inverted test data. For example, when the test data “010” are shifted in from the SI terminal, the flip-flops 30, 31 and 32 output the test data “111”, which are supplied to the input terminals DI0, DI1 and DI2 of the RAM 91. In this state, the test data next to the SI terminal is inverted by the inverter 40 and supplied to the input terminal DI0 of the RAM 91, the output data “1” of the flip-flop 30 is inverted by the inverter 41 and supplied to the input terminal DI1 of the RAM 91, and the output data “1” of the flip-flop 31 is inverted by the inverter 42 and supplied to the input terminal DI2 of the RAM 91.

Subsequently, the selector 100 is switched to its “1” input terminal by placing the loop enabling signal at LOOPEN=1. Then, the output data “1” of the flip-flop 32 is transferred to the input terminal DI0 of the RAM 91 via the inverter 40, thereby placing the data at the input terminals DI0, DI1 and DI2 of the RAM 91 at “000”. Every time the clock pulse is supplied to the flip-flops 30, 31 and 32 in the state the loop enabling signal is set at LOOPEN=1, the data at the input terminals DI0, DI1 and DI2 of the RAM 91 are changed through the inverters 40, 41 and 42, alternating the data between “000” and “111”. When the intended test data “000” or “111” are set, the write operation of the RAM 91 is carried out. The test data write to the RAM 91 is repeated a plurality of times with varying the addresses.

The read and write test of the specified addresses of the RAM 91 is carried out as in the embodiment 6, in which case the loop enabling signal LOOPEN can be set at either “1” or “0”.

Although the write test of the initial data to the RAM 91 is performed by shifting the test data in from the SI terminal such that the outputs of the flip-flops 30, 31 and 32 become “111” in the present embodiment 7, this is not essential. It is also possible to shift the test data in from the SI terminal such that the outputs of the flip-flops 30, 31 and 32 become “000”.

As described above, the present embodiment 7 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently. Furthermore, it offers an advantage of being able to carry out the normal operation mode without supplying the flip-flops 30, 31 and 32 with the clock signal.

Moreover, the present embodiment 7 is configured such that the data supplied to the input terminals DI0-DI2 of the RAM 91 alternate between “111” and “000” every time the clock pulse is supplied to the flip-flops 30, 31 and 32. This is implemented by shifting the test data from the SI terminal to the flip-flops 30, 31 and 32 such that the data becomes “111” or “000” by placing the loop enabling signal at LOOPEN=0, and then by switching the loop enabling signal to LOOPEN=1. Thus, it becomes unnecessary to supply new test data from the SI terminal any more. As a result, the present embodiment 7 offers an advantage of being able to facilitate the test of the RAM 91.

### Embodiment 8

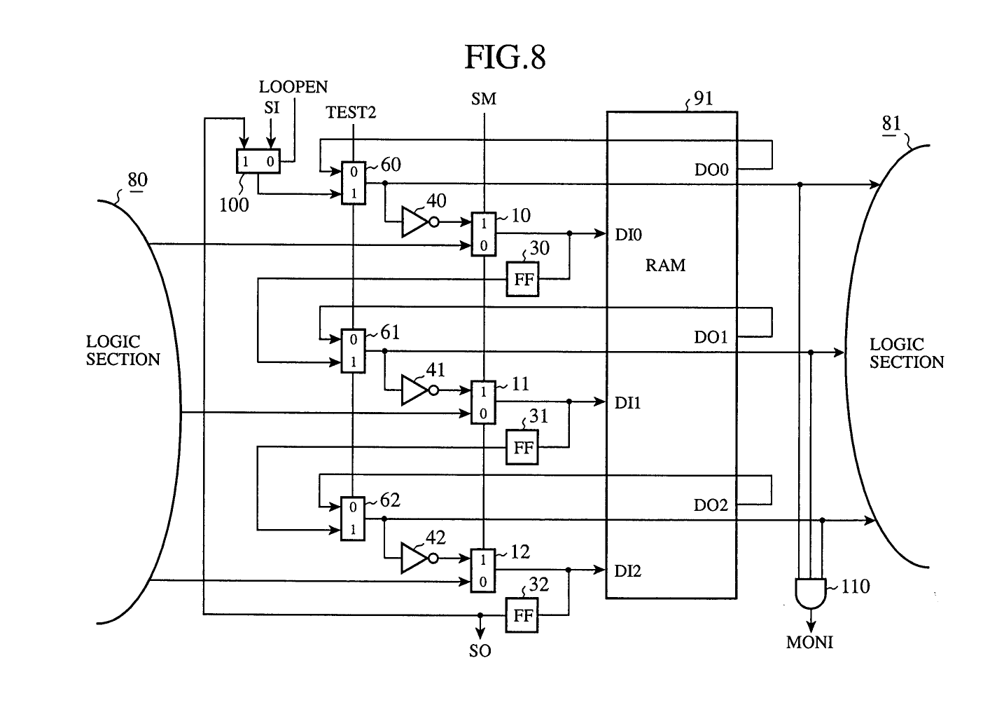

FIG. 8 is a circuit diagram showing a configuration of an embodiment 8 of the semiconductor integrated circuit device in accordance with the present invention. As shown in FIG. 8, the present embodiment 8 includes in addition to the foregoing embodiment 7 of FIG. 7 a gate circuit 110 for monitoring the test result data output from the RAM 91 in a short time. The gate circuit 110 is provided for checking that the output data of the selectors 60, 61 and 62 have the same value. Although FIG. 8 employs an AND gate as the gate circuit 110, any of a NAND gate, OR gate and NOR gate can be used.

Next, the operation of the present embodiment 8 will be described.

The operations in the normal operation mode and in the scan test of the logic sections 80 and 81 are the same as those of the foregoing embodiment 7. In addition, the operation of the write test of the initial data to the RAM 91 is also the same as that of the embodiment 7.

Next, a read and write test from and to specified addresses of the RAM 91 will be described. The selector 100 is switched to its “1” input terminal by placing the loop enabling signal at LOOPEN=1, the selectors 10, 11 and 12 are switched to their “1” input terminals by placing the shift mode signal at SM=1, and the selectors 60, 61 and 62 are switched to their “0” input terminals by placing the test mode signal at TEST2=0.

The read test from specified addresses of the RAM 91 causes the test result data to be output from the output terminals DO0, DO1 and DO2 of the RAM 91, and then transferred to the inputs of the gate circuit 110 via the selectors 60, 61 and 62. In this case, if the test result data are “111”, a monitoring signal MONI output from the gate circuit 110 becomes “1”, and otherwise it becomes “0”. Accordingly, checking the monitoring signal MONI makes it possible to make a decision as to whether the test result data from the output terminals DO0, DO1 and DO2 of the RAM 91 are “111” or not without shifting out the data from the SO terminal.

The test result data from the output terminals DO0, DO1 and DO2 of the RAM 91 are inverted by the inverters 40, 41 and 42 and supplied to the input terminals DI0, DI1 and DI2 of the RAM 91. Then, the inverted test result data are written into the RAM 91. At the same time, supplying the clock pulse to the flip-flops 30, 31 and 32 causes them to store the inverted test result data.

Subsequently, switching the selectors 60, 61 and 62 to their “1” input terminals by placing the test mode signal at TEST2=1 causes the inverted test result data stored in the flip-flops 32, 30 and 31 to be transferred to the inputs of the gate circuit 110 via the selectors 60, 61 and 62. If the test result data are “000”, the inputs of the gate circuit 110 are placed at “111”, and the gate circuit 110 outputs the monitoring signal MONI of “1”. In contrast, if the test result data are other than “000”, the monitoring signal MONI becomes “0”. Thus, checking the monitoring signal MONI makes it possible to make a decision as to whether the test result data output from the output terminals DO0, DO1 and DO2 of the RAM 91 are “000” or not without shifting out the data from the SO terminal. The read and write test of the RAM 91 is repeated a plurality of times with changing the addresses.

As described above, the present embodiment 8 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently. Furthermore, it offers an advantage of being able to carry out the normal operation mode without supplying the flip-flops 30, 31 and 32 with the clock signal.

Moreover, the present embodiment 8 is configured such that the data supplied to the input terminals DI0-DI2 of the RAM 91 alternate between “111” and “000” every time the clock pulse is supplied to the flip-flops 30, 31 and 32. This is implemented by shifting the test data from the SI terminal to the flip-flops 30, 31 and 32 such that the data become “111” or “000” by placing the loop enabling signal at LOOPEN=0, and then by switching the loop enabling signal to LOOPEN=1. Thus, it becomes unnecessary to supply new test data from the SI terminal any more. As a result, the present embodiment 8 offers an advantage of being able to facilitate the test of the RAM 91.

Moreover, the present embodiment 8 can decide as to whether the test result data output from the output terminals DO0, DO1 and DO2 of the RAM 91 are “111” or “000” by only checking the monitoring signal MONI without shifting the data out of the SO terminal. Accordingly, it offers an advantage of being able to facilitate the test of the RAM 91.

### Embodiment 9

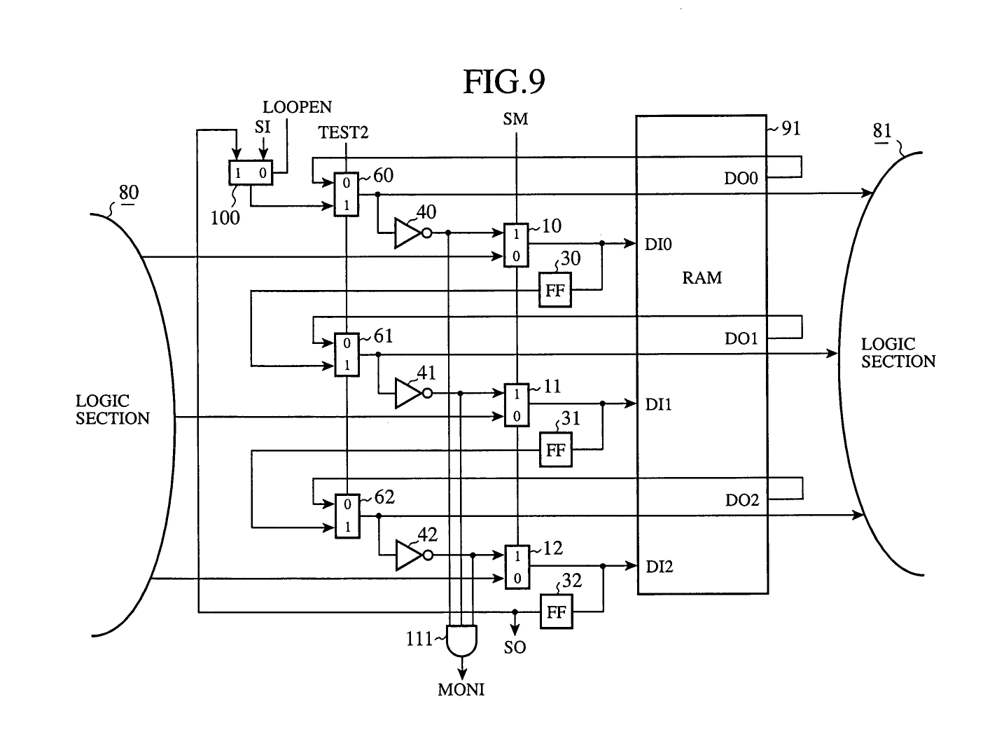

FIG. 9 is a circuit diagram showing a configuration of an embodiment 9 of the semiconductor integrated circuit device in accordance with the present invention. As shown in FIG. 9, the present embodiment 9 includes a gate circuit 111 that corresponds to the gate circuit 110 of the foregoing embodiment 8 in FIG. 8, but is moved from the output side of the selectors 60, 61 and 62 to the output side of the inverters 40, 41 and 42. The gate circuit 111 is provided for checking that the outputs of the inverters 40, 41 and 42 have the same value. Although FIG. 9 employs an AND gate as the gate circuit 111, any of a NAND gate, OR gate and NOR gate can be used.

Next, the operation of the present embodiment 9 will be described.

The operations in the normal operation mode and in the scan test of the logic sections 80 and 81 are the same as those of the foregoing embodiment 7. In addition, the operation of the write test of the initial data to the RAM 91 is also the same as that of the embodiment 7.

Next, a read and write test from and to specified addresses of the RAM 91 will be described. The selector 100 is switched to its “1” input terminal by placing the loop enabling signal at LOOPEN=1, the selectors 10, 11 and 12 are switched to their “1” input terminals by placing the shift mode signal at SM=1, and the selectors 60, 61 and 62 are switched to their “0” input terminals by placing the test mode signal at TEST2=0.

The read test from specified addresses of the RAM 91 causes the test result data to be output from the output terminals DO0, DO1 and DO2 of the RAM 91, and then transferred to the inputs of the gate circuit 111 via the selectors 60, 61 and 62 and inverters 40, 41 and 42 that invert the test result data. In this case, if the test result data is “000”, a monitoring signal MONI output from the gate circuit 111 becomes “1”, and otherwise it becomes “0”. Accordingly, checking the monitoring signal MONI makes it possible to make a decision as to whether the test result data from the output terminals DO0, DO1 and DO2 of the RAM 91 are “000” or not without shifting out the data from the SO terminal.

The test result data from the output terminals DO0, DO1 and DO2 of the RAM 91 are inverted by the inverters 40, 41 and 42 and supplied to the input terminals DI0, DI1 and DI2 of the RAM 91. Then, the inverted test result data are written into the RAM 91. At the same time, supplying one clock pulse to the flip-flops 30, 31 and 32 causes them to store the inverted test result data.

Subsequently, switching the selectors 60, 61 and 62 to their “1” input terminals by placing the test mode signal at TEST2=1 causes the inverted test result data stored in the flip-flops 32, 30 and 31 to be transferred to the selectors 60, 61 and 62. The inverted test result data output from the selectors 60, 61 and 62 are transferred to the gate circuit 111 after inverted by the inverters 40, 41 and 42, again. If the test result data are “111”, the inputs of the gate circuit 111 are placed at “111”, and the gate circuit 111 outputs the monitoring signal MONI of “1”. In contrast, if the test result data are other than “111”, the monitoring signal MONI becomes “0”. Thus, checking the monitoring signal MONI makes it possible to make a decision as to whether the test result data output from the output terminals DO0, DO1 and DO2 of the RAM 91 are “111” or not without shifting out the data from the SO terminal. The read and write test of the RAM 91 is repeated a plurality of times with changing the addresses.

As described above, the present embodiment 9 can test the RAM 91 in isolation without increasing the scale of the test circuit. In addition, it can switch the test data to be written into the RAM 91 between all zero (“000”) and all one (“111”) at one clock cycle. As a result, it offers an advantage of being able to test the RAM 91 efficiently. Furthermore, it offers an advantage of being able to carry out the normal operation mode without supplying the flip-flops 30, 31 and 32 with the clock signal.

Moreover, the present embodiment 9 is configured such that the data supplied to the input terminals DI0-DI2 of the RAM 91 alternate between “111” and “000” every time the clock pulse is supplied to the flip-flops 30, 31 and 32. This is implemented by shifting the test data from the SI terminal to the flip-flops 30, 31 and 32 such that the data become “111” or “000” by placing the loop enabling signal at LOOPEN=0, and then by switching the loop enabling signal to LOOPEN=1. Thus, it becomes unnecessary to supply new test data from the SI terminal any more. As a result, the present embodiment 9 offers an advantage of being able to facilitate the test of the RAM 91.

Moreover, the present embodiment 9 can decide as to whether the test result data output from the output terminals DO0, DO1 and DO2 of the RAM 91 are “000” or “111” by only checking the monitoring signal MONI without shifting the data out of the SO terminal. Accordingly, it offers an advantage of being able to facilitate the test of the RAM 91.

### Embodiment 10

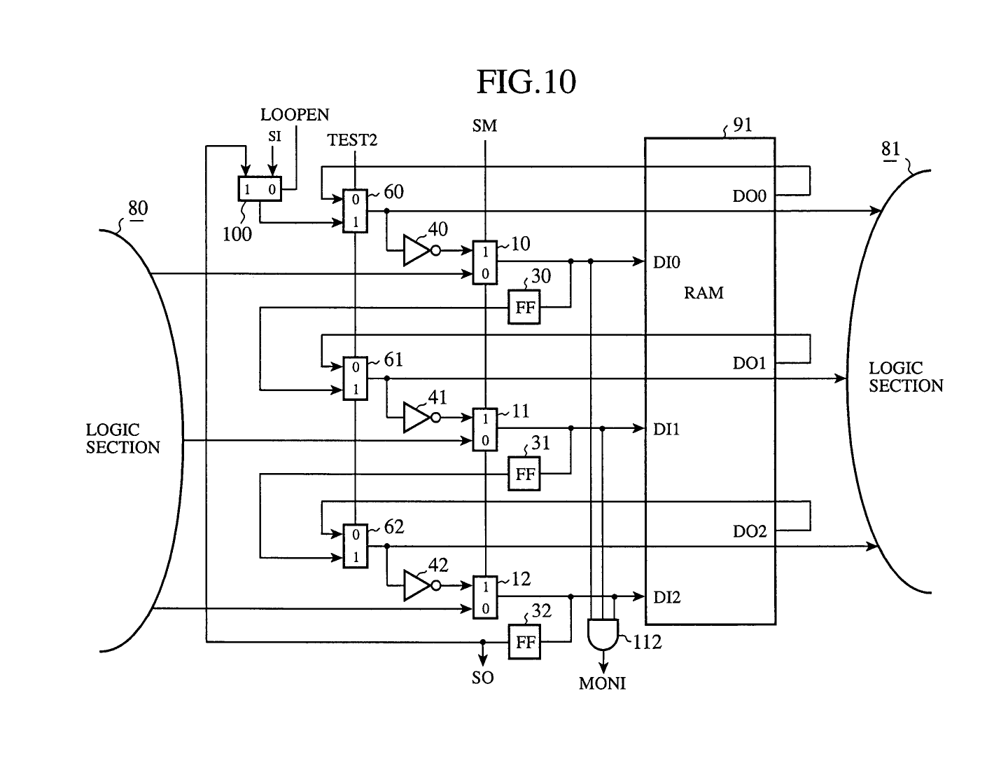

FIG. 10 is a circuit diagram showing a configuration of an embodiment 10 of the semiconductor integrated circuit device in accordance with the present invention. As shown in FIG. 10, the present embodiment 10 includes a gate circuit 112 that corresponds to the gate circuit 110 of the foregoing embodiment 8 in FIG. 8, but is moved from the output side of the selectors 60, 61 and 62 to the output side of the selectors 10, 11 and 12. The gate circuit 112 is provided for checking that the outputs of the selectors 10, 11 and 12 have the same value. Although FIG. 10 employs an AND gate as the gate circuit 112, any of a NAND gate, OR gate and NOR gate can be used.

Next, the operation of the present embodiment 10 will be described.

The operations in the normal operation mode and in the scan test of the logic sections 80 and 81 are the same as those of the foregoing embodiment 7. In addition, the operation of the write test of the initial data to the RAM 91 is also the same as that of the embodiment 7. Furthermore, a read and write test from and to specified addresses of the RAM 91 is the same as that of the foregoing embodiment 9 except that the gate circuit 112 makes a decision as to whether the test result data output from the output terminals DO0, DO1 and DO2 of the RAM 91 are “000” or “111” from the data output from the selectors 10, 11 and 12.

As described above, the present embodiment 10 offers the same advantages as the embodiment 9.

### Embodiment 11

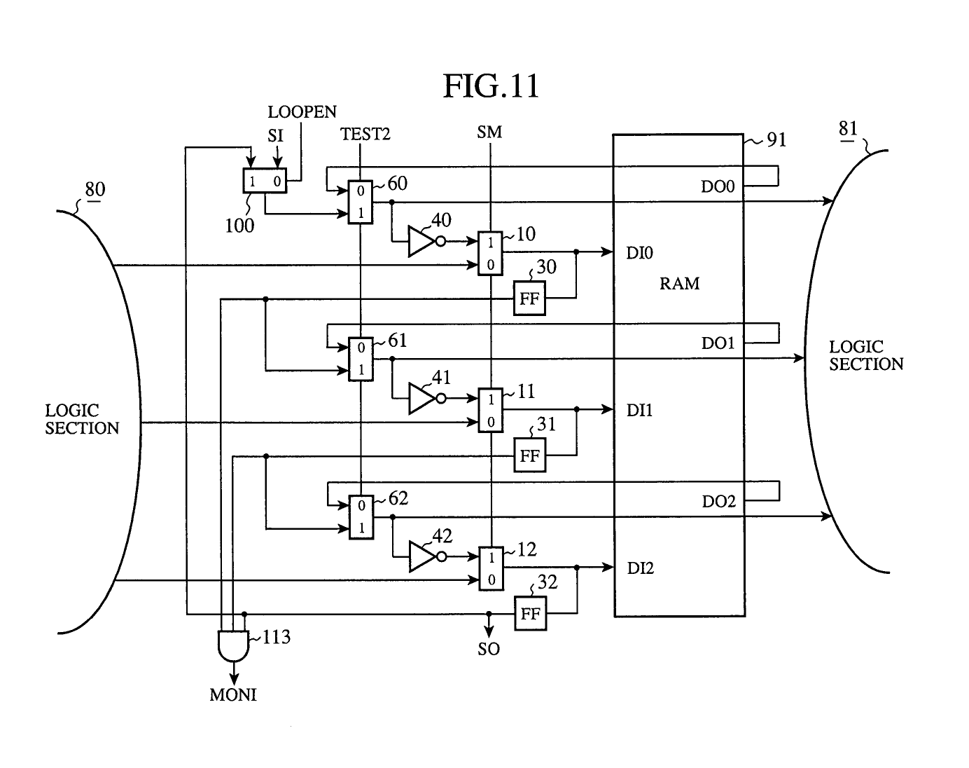

FIG. 11 is a circuit diagram showing a configuration of an embodiment 11 of the semiconductor integrated circuit device in accordance with the present invention. As shown in FIG. 11, the present embodiment 11 includes a gate circuit 113 that corresponds to the gate circuit 110 of the foregoing embodiment 8 in FIG. 8, but is moved from the output side of the selectors 60, 61 and 62 to the output side of the flip-flops 30, 31 and 32. The gate circuit 113 is provided for checking that the outputs of the flip-flops 30, 31 and 32 have the same value. Although FIG. 11 employs an AND gate as the gate circuit 113, any of a NAND gate, OR gate and NOR gate can be used.

Next, the operation of the present embodiment 11 will be described.

The operations in the normal operation mode and in the scan test of the logic sections 80 and 81 are the same as those of the foregoing embodiment 7. In addition, the operation of the write test of the initial data to the RAM 91 is also the same as that of the embodiment 7.

Next, a read and write test from and to specified addresses of the RAM 91 will be described. The selector 100 is switched to its “1” input terminal by placing the loop enabling signal at LOOPEN=1, the selectors 10, 11 and 12 are switched to their “1” input terminals by placing the shift mode signal at SM=1, and the selectors 60, 61 and 62 are switched to their “0” input terminals by placing the test mode signal at TEST2=0.

The read test from specified addresses of the RAM 91 causes the test result data to be output from the output terminals DO0, DO1 and DO2 of the RAM 91. The test result data pass through the selectors 60, 61 and 62 and selectors 10, 11 and 12 and are inverted by the inverters 40, 41 and 42. Then, the inverted test result data are supplied to the inputs of the flip-flops 30, 31 and 32 and to the input terminals DI0, DI1 and DI2 of the RAM 91.

Subsequently, the inverted test result data are written into the RAM 91. At the same time, supplying one clock pulse to the flip-flops 30, 31 and 32 causes them to store the inverted test result data. Thus, the inverted test result data are transferred to the inputs of the gate circuit 113.

In this case, if the test result data are “000”, the output data of the flip-flops 30, 31 and 32 are placed at “111”, and the gate circuit 113 outputs the monitoring signal MONI of “1”. In contrast, if the test result data are other than “000”, the monitoring signal MONI becomes “0”. Thus, checking the monitoring signal MONI makes it possible to make a decision as to whether the test result data output from the output terminals DO0, DO1 and DO2 of the RAM 91 are “000” or not without shifting out the data from the SO terminal.

Subsequently, switching the selectors 60, 61 and 62 to their “1” input terminals by placing the test mode signal at TEST2=1 causes the inverted test result data stored in the flip-flops 32, 30 and 31 to be transferred to the selectors 60, 61 and 62. The inverted test result data output from the selectors 60, 61 and 62 are inverted by the inverters 40, 41 and 42, again, to become the test result data, which are transferred to the inputs of the flip-flops 30, 31 and 32 via the selectors 10, 11 and 12. Then, supplying one clock pulse to the flip-flops 30, 31 and 32 causes them to store the test result data, and to transfer the test result data to the inputs of the gate circuit 113.

If the test result data are “111”, the inputs of the gate circuit 113 are placed at “111”, and the gate circuit 113 outputs the monitoring signal MONI of “1”. In contrast, if the test result data are other than “111”, the monitoring signal MONI becomes “0”. Thus, checking the monitoring signal MONI makes it possible to make a decision as to whether the test result data output from the output terminals DO0, DO1 and DO2 of the RAM 91 are “111” or not without shifting out the data from the SO terminal. The read and write test of the RAM 91 is repeated a plurality of times with changing the addresses.

As described above, the present embodiment 11 offers the same advantages as those of the embodiment 9.

Incidentally, the present invention need not be applied to all the input/output terminals of the functional block 90 or RAM 91, but can achieve its advantages by applying it to a part of them. For example, when the number of the input terminals of the functional block 90 differs from that of its output terminals, the present invention can be implemented by making pairs, with matching their number to the smaller number between the input and output terminals.

What is claimed is:

1. A semiconductor integrated circuit device including:
a first logic section;
a second logic section;
a functional block connected between said first logic section and said second logic section; and
a scan path that includes parallel paths between outputs of said first logic section and inputs of said functional block, and a serial shift path for serially transferring data from a scan-in terminal to a scan-out terminal, wherein said scan path comprises:
a plurality of first selectors for switching between said parallel paths and said serial shift path to supply said functional block with one of a set of outputs of said first logic section and a set of outputs of said serial shift path;
a plurality of flip-flops for storing output data of said plurality of first selectors; and
a plurality of second selectors interposed into said serial shift path of the scan path, for connecting one of a set of outputs of said functional block and a set of outputs of said serial shift path to inputs of said second logic section and to inputs of said plurality of said first selectors, and wherein
when carrying out a test of said functional block, test data on said serial shift path of said scan path are shifted in to said functional block via said second selectors and said first selectors, and test result data said functional block produces are output from said serial shift path after switching said second selectors.

2. The semiconductor integrated circuit device according to claim 1, wherein said parallel paths consist of said plurality of first selectors, and wherein connecting points of outputs of said first selectors and said flip-flops on said serial shift path are connected to the inputs of said functional block.

3. The semiconductor integrated circuit device according to claim 1, wherein said functional block consists of a RAM (Random Access Memory), and said scan path includes a plurality of inverters interposed into said serial shift path.

4. The semiconductor integrated circuit device according to claim 3, wherein said inverters are connected to the outputs of said second selectors.

5. The semiconductor integrated circuit device according to claim 3, wherein said scan path further comprises a third selector connected between said scan-out terminal and said scan-in terminal for feeding an output of said serial shift path back to an input of said serial shift path.

6. The semiconductor integrated circuit device according to claim 5, further comprising a gate circuit for checking that data output from said functional block and passed through said second selectors take a specified value.

7. The semiconductor integrated circuit device according to claim 5, further comprising a gate circuit for checking that data output from said functional block and passed through said inverters take a specified value.

8. The semiconductor integrated circuit device according to claim 5, further comprising a gate circuit for checking that data output from said functional block and passed through said first selectors take a specified value.

9. The semiconductor integrated circuit device according to claim 5, further comprising a gate circuit for checking that data output from said functional block and stored in said flip-flops take a specified value.
